(19) United States
(12) Patent Application Publication
(10) Pub. No.: US 2026/0255745 A1
(43) Pub. Date: Aug. 27, 2026

(54) LIGHT-EMITTING DEVICE AND IMAGE DISPLAY APPARATUS

(71) Applicant: SONY SEMICONDUCTOR SOLUTIONS CORPORATION, KANAGAWA (JP)

(72) Inventors: HIROSHI TANAKA, KANAGAWA (JP); NOBUTOSHI FUJII, KANAGAWA (JP)

(21) Appl. No.: 19/162,972

(22) PCT Filed: Feb. 15, 2024
(86) PCT No.: PCT/JP2024/005347

§ 371 Date: Sep. 8, 2025

(30) Foreign Application Priority Data
Mar. 29, 2023 (JP) 2023-054169

(51) Int. Cl. H10H 20/851; H10H 20/01; H10H 20/841; H10H 29/01; H10H 29/49

(52) U.S. Cl. CPC H10H 20/8514; H10H 20/034; H10H 20/0361; H10H 20/841; H10H 29/012; H10H 29/49

(57) ABSTRACT

A light-emitting device according to one embodiment of the present disclosure includes: a drive substrate; a compound semiconductor layer electrically coupled to the drive substrate, the compound semiconductor layer including a first surface opposed to the drive substrate, a second surface that is opposite to the first surface and that serves as a light output surface, and a light-emitting region between the first surface and the second surface; a separation section separating, from the first surface toward the second surface, the compound semiconductor layer into a plurality of pieces; and an embedding layer that is provided between the drive substrate and the compound semiconductor layer, that is embedded in the separation section, and that has a gap between adjacent pieces of the compound semiconductor layer.

### TECHNICAL FIELD

The present disclosure relates to a light-emitting device and an image display apparatus provided with the light-emitting device.

### BACKGROUND ART

For example, Patent Literature 1 discloses a light source device with a separation trench separating a light-emitting element layer into a plurality of island shape pieces, the separation trench embedded with a light-blocking layer including a material different from a material of the light-emitting element layer.

### CITATION LIST

### Patent Literature

Patent Literature 1: Japanese Unexamined Patent Application Publication No. 2022-70551

### SUMMARY OF THE INVENTION

Incidentally, in a light-emitting device provided with a plurality of light-emitting elements including a compound semiconductor arranged in an array, enhancement in reliability is desired.

It is desirable to provide a light-emitting device and an image display apparatus that make it possible to enhance such reliability.

A light-emitting device according to one embodiment of the present disclosure includes: a drive substrate; a compound semiconductor layer electrically coupled to the drive substrate, the compound semiconductor layer including a first surface opposed to the drive substrate, a second surface that is opposite to the first surface and that serves as a light output surface, and a light-emitting region between the first surface and the second surface; a separation section separating, from the first surface toward the second surface, the compound semiconductor layer into a plurality of pieces; and an embedding layer that is provided between the drive substrate and the compound semiconductor layer, that is embedded in the separation section, and that has a gap between adjacent pieces of the compound semiconductor layer.

An image display apparatus according to one embodiment of the present disclosure includes a light-emitting device. As the light-emitting device, the light-emitting device according to one embodiment of the present disclosure described above is included.

In the light-emitting device according to one embodiment of the present disclosure and the image display apparatus according to one embodiment, the separation section separates, from the first surface toward the second surface, the compound semiconductor layer into a plurality of pieces, the compound semiconductor layer being electrically coupled to the drive substrate and including the first surface opposed to the drive substrate and the second surface that is opposite to the first surface and that serves as a light output surface. The separation section is embedded with the embedding layer provided between the drive substrate and the compound semiconductor layer, and the embedding layer has the gap between adjacent pieces of the compound semiconductor layer. This allows an expansion of the compound semiconductor layer due to, for example, annealing during the manufacturing process to be absorbed by the gap, preventing occurrence of cracks.

### BRIEF DESCRIPTION OF DRAWING

FIG. 1 is a schematic cross-sectional view illustrating an example of a configuration of a light-emitting device according to an embodiment of the present disclosure.

FIG. 2 schematically illustrates an example of an overall configuration in plan view of the light-emitting device illustrated in FIG. 1.

FIG. 3 schematically illustrates the configuration in plan view of the light-emitting device illustrated in FIG. 2 with a portion of the configuration enlarged.

FIG. 4A is a schematic cross-sectional view illustrating an example of a manufacturing process of the light-emitting device illustrated in FIG. 1.

FIG. 4B is a schematic cross-sectional view illustrating a process following FIG. 4A.

FIG. 4C is a schematic cross-sectional view illustrating a process following FIG. 4B.

FIG. 4D is a schematic cross-sectional view illustrating a process following FIG. 4C.

FIG. 4E is a schematic cross-sectional view illustrating a process following FIG. 4D.

FIG. 4F is a schematic cross-sectional view illustrating a process following FIG. 4E.

FIG. 4G is a schematic cross-sectional view illustrating a process following FIG. 4F.

FIG. 4H is a schematic cross-sectional view illustrating a process following FIG. 4G.

FIG. 4I is a schematic cross-sectional view illustrating a process following FIG. 4H.

FIG. 4J is a schematic cross-sectional view illustrating a process following FIG. 4I.

FIG. 4K is a schematic cross-sectional view illustrating a process following FIG. 4J.

FIG. 5A is a schematic cross-sectional view illustrating a process following FIG. 4K.

FIG. 5B is a schematic cross-sectional view illustrating a process following FIG. 5A.

FIG. 5C is a schematic cross-sectional view illustrating a process following FIG. 5B.

FIG. 5D is a schematic cross-sectional view illustrating a process following FIG. 5C.

FIG. 5E is a schematic cross-sectional view illustrating a process following FIG. 5D.

FIG. 5F is a schematic cross-sectional view illustrating a process following FIG. 5E.

FIG. 5G is a schematic cross-sectional view illustrating a process following FIG. 5F.

FIG. 5H is a schematic cross-sectional view illustrating a process following FIG. 5G.

FIG. 5I is a schematic cross-sectional view illustrating a process following FIG. 5H.

FIG. 5J is a schematic cross-sectional view illustrating a process following FIG. 5I.

FIG. 5K is a schematic cross-sectional view illustrating a process following FIG. 5J.

FIG. 5L is a schematic cross-sectional view illustrating a process following FIG. 4K.

FIG. 5M is a schematic cross-sectional view illustrating a process following FIG. 5L.

FIG. 5N is a schematic cross-sectional view illustrating a process following FIG. 5M.

FIG. 5O is a schematic cross-sectional view illustrating a process following FIG. 5N.

FIG. 5P is a schematic cross-sectional view illustrating a process following FIG. 50.

FIG. 5Q is a schematic cross-sectional view illustrating a process following FIG. 5P.

FIG. 5R is a schematic cross-sectional view illustrating a process following FIG. 5Q.

FIG. 5S is a schematic cross-sectional view illustrating a process following FIG. 5R.

FIG. 5T is a schematic cross-sectional view illustrating a process following FIG. 5S.

FIG. 5U is a schematic cross-sectional view illustrating a process following FIG. 5T.

FIG. 5V is a schematic cross-sectional view illustrating a process following FIG. 5U.

FIG. 5W is a schematic cross-sectional view illustrating a process following FIG. 5V.

FIG. 6 schematically illustrates a configuration in plan view of a light-emitting device according to Modification 1 of the present disclosure with a portion of the configuration enlarged.

FIG. 7 is a perspective view illustrating an example of a configuration of an image display apparatus according to an application example of the present disclosure.

FIG. 8 is a schematic diagram illustrating an example of a wiring layout of the image display apparatus illustrated in FIG. 7.

FIG. 9 is a perspective view illustrating an example of a configuration of an image display apparatus according to an application example of the present disclosure.

FIG. 10 is a perspective view illustrating a configuration of a mounting substrate illustrated in FIG. 9.

FIG. 11 is a perspective view illustrating a configuration of a unit substrate illustrated in FIG. 10.

FIG. 12 is a diagram illustrating an example of an image display apparatus according to an application example of the present disclosure.

### MODES FOR CARRYING OUT THE INVENTION

Hereinafter, one embodiment of the present disclosure is described in detail with reference to the drawings. The following description is a specific example of the present disclosure, and thus the present disclosure is not limited to the following aspect. Moreover, the present disclosure does not limit the disposition, dimensions, dimension ratios, and the like of respective components illustrated in the drawings thereto. Note that the description is given in the following order.
1. First Embodiment (an example that a sapphire substrate is patterned on a light output surface of a light-emitting element)
   1-1. Configuration of Light-emitting Device
   1-2. Manufacturing Method of Light-emitting Device
   1-3. Operations and Effects
2. Modification (another example of a configuration of the light-emitting device)
3. Application Examples

### 1. Embodiment

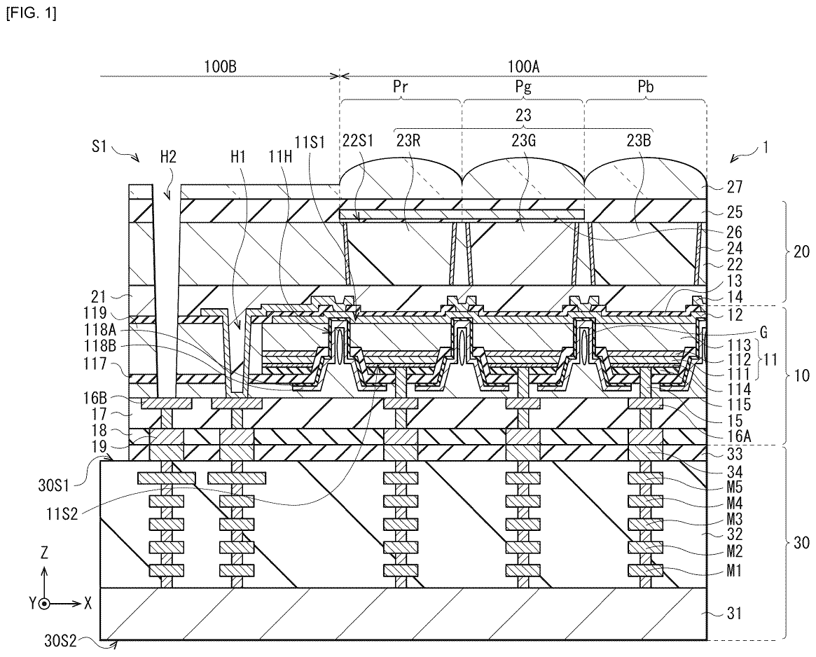

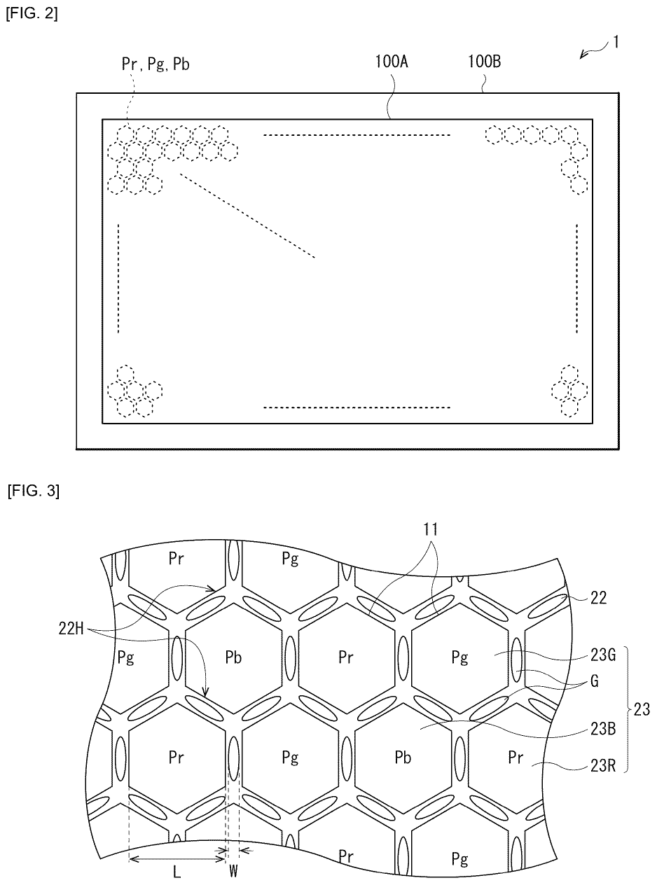

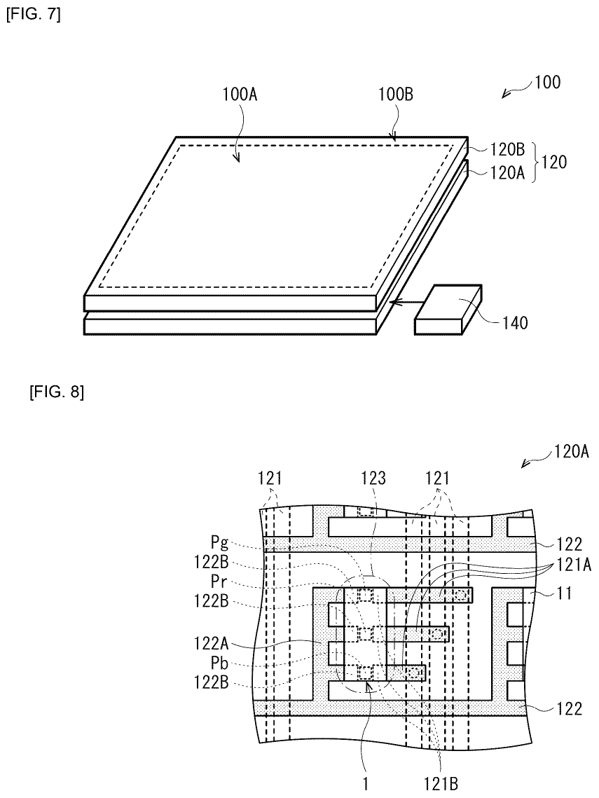

FIG. 1 schematically illustrates an example of a cross-sectional configuration of a light-emitting device (light-emitting device 1) according to one embodiment of the present disclosure. FIG. 2 schematically illustrates an example of an overall configuration in plan view of the light-emitting device 1 illustrated in FIG. 1. The light-emitting device 1 is suitably applicable for an image display apparatus (for example, image display apparatus 100, see FIG. 7) referred to as a so-called LED display.

The light-emitting device 1 according to the present embodiment includes a drive substrate 30 including a front surface (surface 30S1) and a back surface (surface 30S2) opposed to each other and includes, stacked on the surface 30S1 side, a compound semiconductor layer 110 electrically coupled to the drive substrate 30. The compound semiconductor layer 110 includes a surface 11S1 serving as a light output surface and a surface 11S2 that is opposite to the surface 11S1 and that is opposed to the drive substrate 30. The compound semiconductor layer 110 is separated, from the surface 11S2 side, into a plurality of pieces by a separation section 11H to form a plurality of light-emitting elements 11 arranged in an array in a display region 100A, for example. The separation section 11H is embedded with an embedding layer 119 provided between the drive substrate 30 and the compound semiconductor layer 110, and the embedding layer 119 has a gap G between adjacent ones of the light-emitting elements 11.

Here, the drive substrate 30 corresponds to a specific example of the “drive substrate” in the embodiment of the present disclosure. The compound semiconductor layer 110 corresponds to a specific example of the “compound semiconductor layer” in the embodiment of the present disclosure. The surface 11S1 corresponds to a specific example of the “second surface” in the embodiment of the present disclosure. The surface 11S2 corresponds to a specific example of the “first surface” in the embodiment of the present disclosure. The separation section 11H corresponds to a specific example of the “separation section” in the embodiment of the present disclosure. The embedding layer 119 corresponds to a specific example of the “embedding layer” in the embodiment of the present disclosure. The gap G corresponds to a specific example of the “gap” in the embodiment of the present disclosure.

### (1-1. Configuration of Light-emitting Device)

The light-emitting device 1 includes the display region 100A and a frame region 100B, the display region 100A including the plurality of light-emitting elements 11 arranged in an array two-dimensionally, the frame region 100B provided around the display region 100A. For example, the light-emitting device 1 includes the drive substrate 30 including the front surface (surface 30S1) and the back surface (surface 30S2) opposed to each other and includes, stacked on the surface 30S1 side, a light-emitting section 10 and a wavelength conversion section 20 in this order, the light-emitting section 10 including the plurality of light-emitting elements 11 arranged in an array.

The light-emitting section 10 includes, as described above, the plurality of light-emitting elements 11 arranged in an array two-dimensionally in the display region 100A. For example, the plurality of light-emitting elements 11 each has a substantially equilateral hexagonal shape, for example as illustrated in FIG. 3, and is arranged in, for example, honeycomb-like. On the surface 11S1 side of the plurality of light-emitting elements 11, an electrode layer 12, an insulating layer 13, and an extraction electrode 14 are provided in this order. On the surface 11S2 side of the plurality of light-emitting elements 11, an electrode layer 114, an insulating layer 115, and a protection layer 117 are provided for each element, an insulating film 118A and a reflection film 118B are provided continuously over the plurality of light-emitting elements 11, and the embedding layer 119 embedded with the plurality of light-emitting elements 11 is provided. Further, on the surface 11S2 side of the plurality of light-emitting elements 11, a plug 15, an insulating layer 17, and an insulating layer 18 are provided in this order, the plug 15 provided for each element, the insulating layer 17 including pads 16A and pad electrodes 16B, the insulating layer 18 including pads 19 that combine the light-emitting section 10 and the drive substrate 30 electrically and physically.

Each light-emitting element 11 corresponds to a specific example of the “light-emitting element” in the embodiment of the present disclosure. The light-emitting element 11 is a solid light-emitting element that emits light in a predetermined wavelength bandwidth from the surface 11S1, the light-emitting element 11 including, for example, a light-emitting diode (LED) chip. The LED chip refers to one in a state taken out from a wafer used for crystal growth, not one of a package-type covered with molded resin or the like. The LED chip has, for example, a size of 5 μm or more and 100 μm or less and is a so-called micro LED.

The light-emitting element 11 includes a first electric conductivity type layer 111 and a second electric conductivity type layer 113 stacked in this order, and a top surface of the second electric conductivity type layer 113 serves as the light output surface (surface 11S1). A light-emitting region 112 is provided between the first electric conductivity type layer 111 and the second electric conductivity type layer 113. From the light-emitting region 112, for example, light in a blue bandwidth of 430 nm or more and 500 nm or less is extracted. In addition, for example, light (ultraviolet light) with a wavelength corresponding to an ultraviolet region may be extracted from the light-emitting region.

The first electric conductivity type layer 111 includes, for example, a GaN-based semiconductor material of p-type. The second electric conductivity type layer 113 includes, for example, a GaN-based semiconductor material of n-type.

The separation section 11H is provided to separate the compound semiconductor layer 110, as described above, to form the light-emitting element 11 per pixel (for example, red color pixel Pr, green color pixel Pg, and blue color pixel Pb). The separation section 11H penetrates the compound semiconductor layer 110 from the surface 11S2 side toward the surface 11S1 side. In the separation section 11H, the insulating film 118A and the reflection film 118B are provided in this order. Furthermore, in the separation section 11H, the embedding layer 119 including the gap G is embedded. Details of the gap G will be described below.

The electrode layer 12 is provided continuously on the surface 11S1 of respective ones of the plurality of light-emitting elements 11, as a common electrode for the plurality of light-emitting elements 11. The electrode layer 12 is in ohmic contact with the second electric conductivity type layer 113. The electrode layer 12 includes a transparent electrode material such as ITO, indium zinc oxide (IZO), tin oxide (SnO), or TiO, for example.

Irregularities formed on the plurality of light-emitting elements 11 are embedded in the insulating layer 13. The insulating layer 13 includes, for example, silicon oxide (SiO), silicon nitride (SiN), or the like.

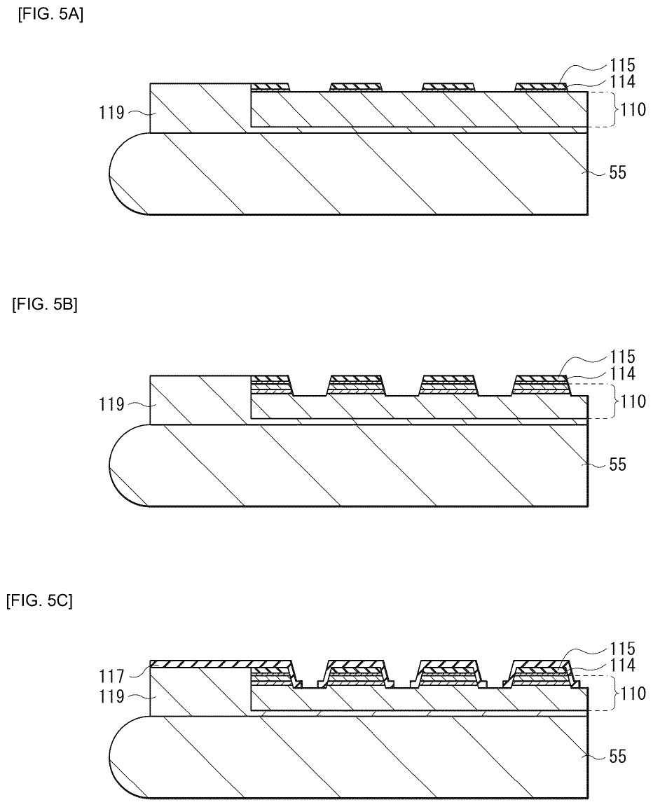

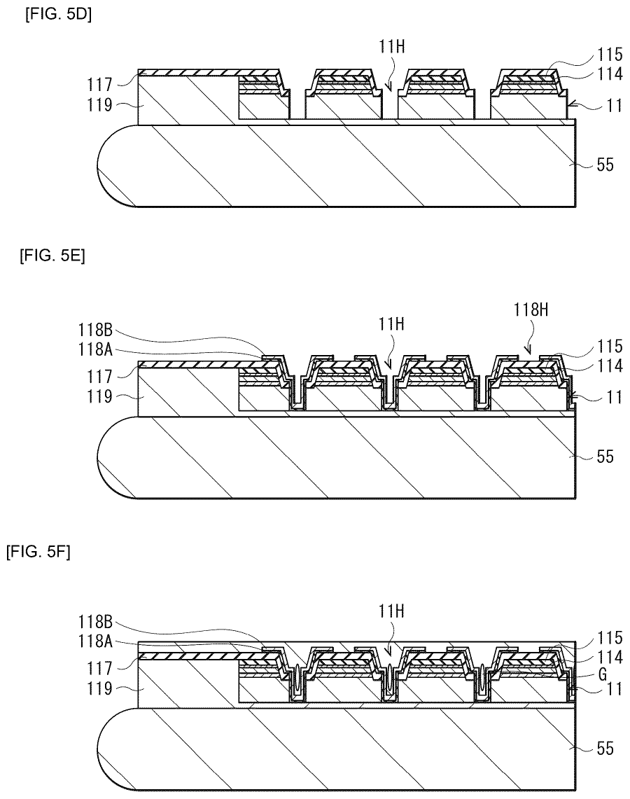

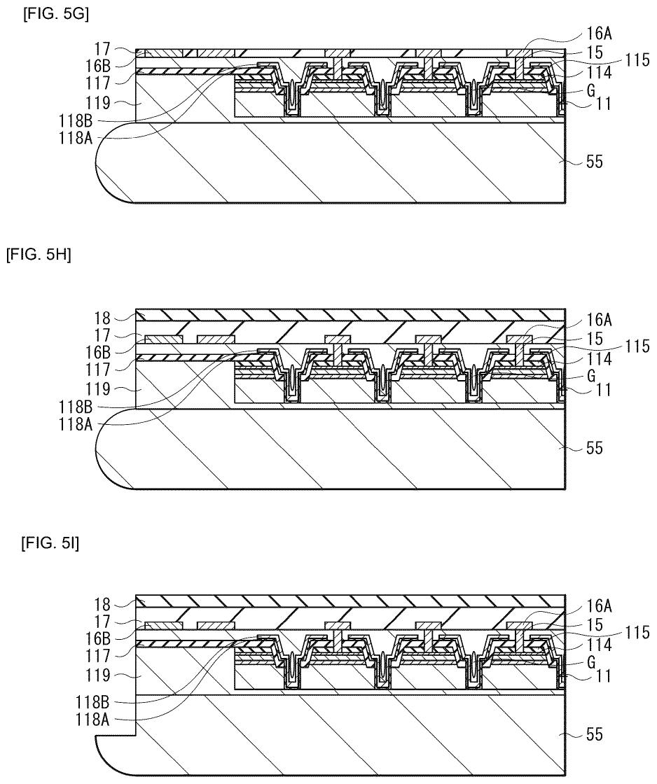

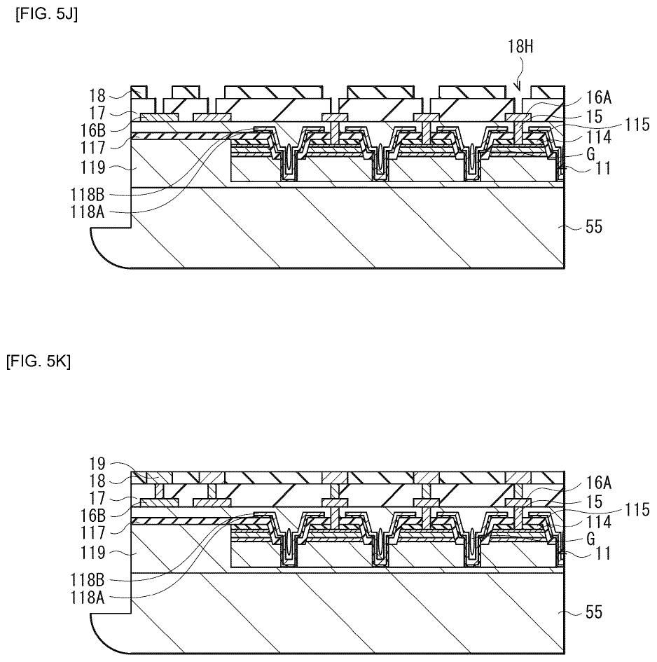

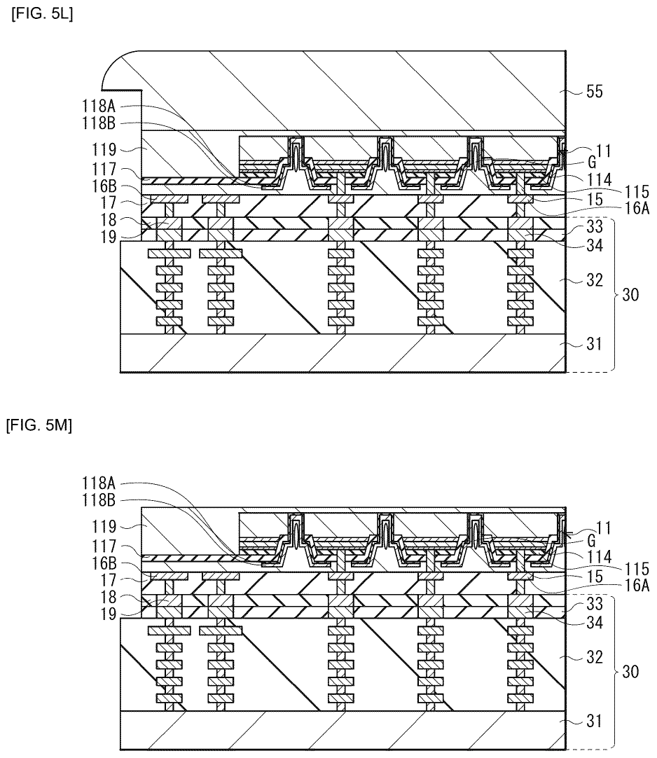

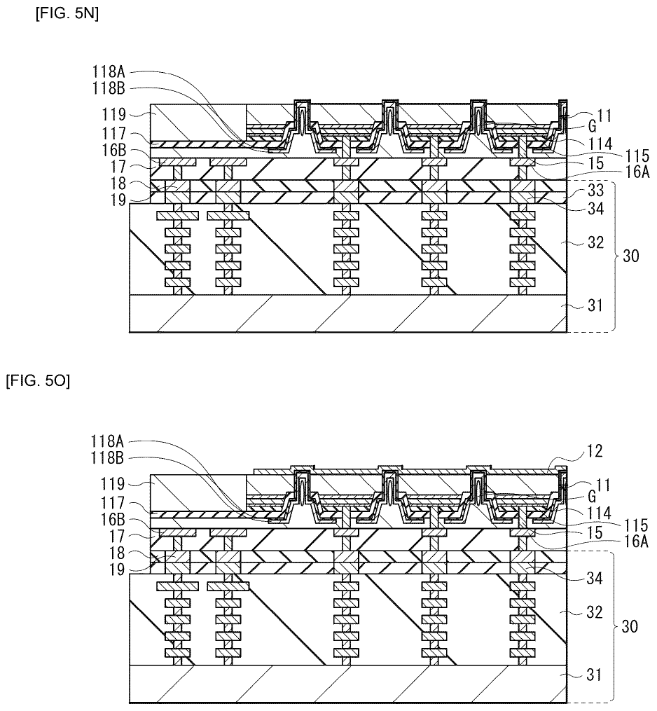

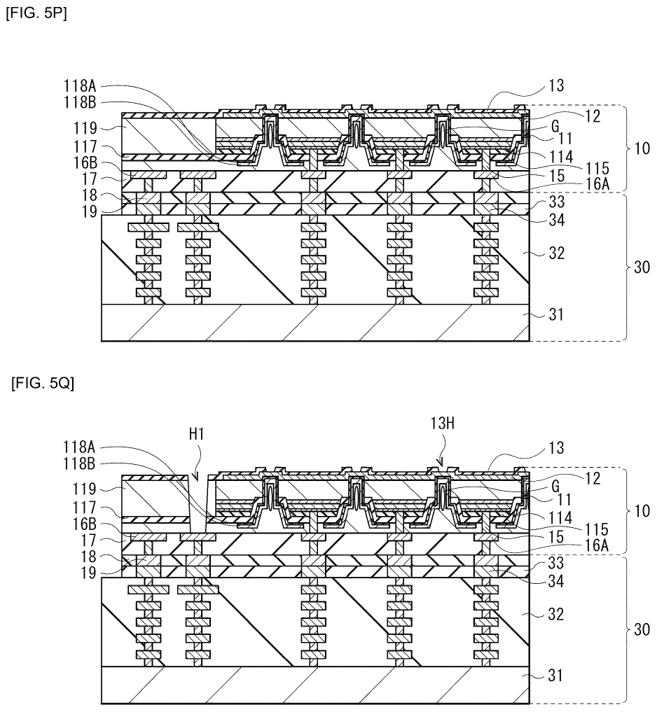

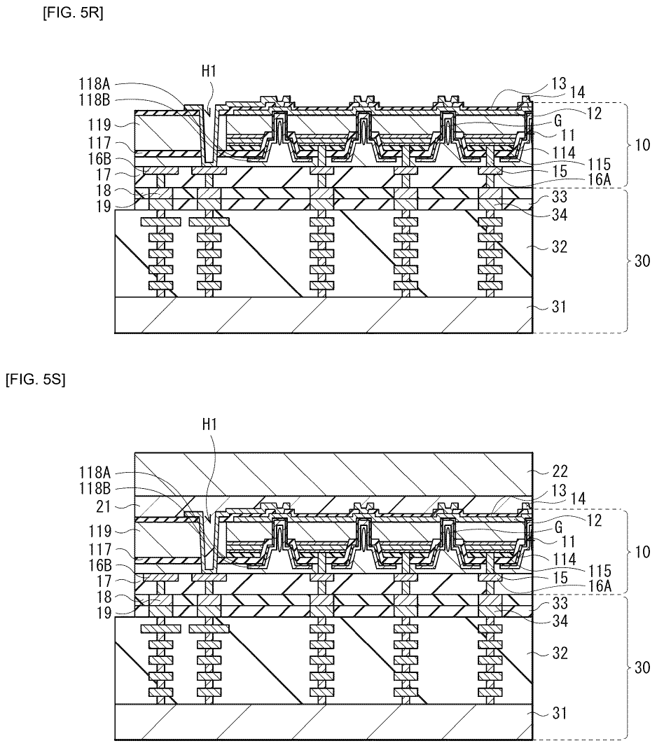

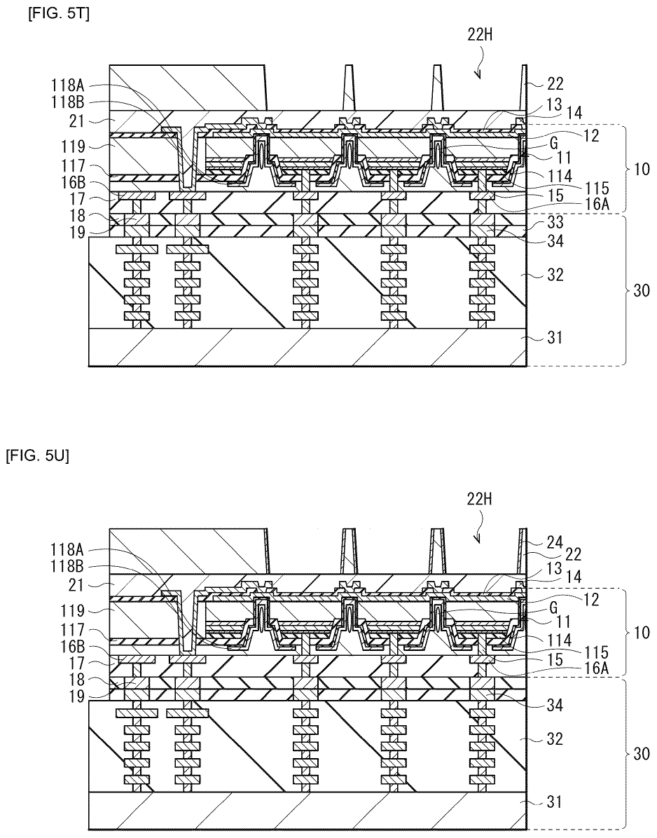

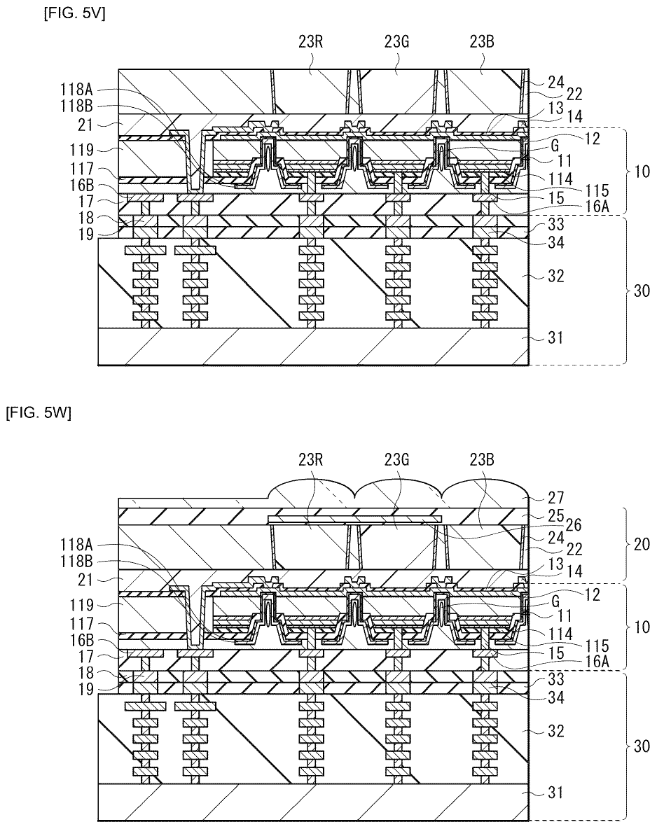

The extraction electrode 14 is provided to apply a voltage to the second electric conductivity type layer 113 of each of the plurality of light-emitting elements 11. The extraction electrode 14 is electrically coupled to the electrode layer 12, for example, via an opening 13H (see FIG. 5Q) provided in the insulating layer 13 between adjacent ones of the light-emitting elements 11. In the display region 100A, the extraction electrode 14 is provided continuously between adjacent ones of the light-emitting elements 11 avoiding the surface 11S1 of each the plurality of light-emitting elements 11 arranged, for example, in honeycomb-like to reach a portion of the frame region 100B. The extraction electrode 14 in the frame region 100B is electrically coupled to any of the pad electrodes 16B via an opening H1 penetrating the insulating layer 13, embedding layer 119, and protection layer 117. The extraction electrode 14 is formed using, for example, a multilayer film (Ti/Al) including titanium (Ti) and aluminum (Al) or a multilayer film (Cr/Au) including chromium (Cr) and gold (Au).

The electrode layer 114 is provided on a bottom surface (surface 11S2) of the first electric conductivity type layer 111 of each light-emitting element 11. The electrode layer 114 is in ohmic contact with the first electric conductivity type layer 111. The electrode layer 114 is formed using, for example, a multilayer film (Ni/Au) including nickel (Ni) and gold (Au) or a transparent electric conductive material such as ITO.

The insulating layer 115 is provided on the electrode layer 114. The insulating layer 115 includes, for example, silicon oxide (SiO), silicon nitride (SiN), or the like.

The light-emitting element 11 has a mesa shape including the first electric conductivity type layer 111, the light-emitting region 112, and a portion of the second electric conductivity type layer 113, on the drive substrate 30 side. The surface 11S2 of the light-emitting element 11 in such a mesa shape and a side surface of each of the first electric conductivity type layer 111, the light-emitting region 112, and the portion of the second electric conductivity type layer 113 are covered with the protection layer 117. The protection layer 117 includes, for example, silicon oxide (SiO), silicon nitride (SiN), or the like.

Moreover, a side surface of the second electric conductivity type layer 113, upper than the protection layer 117 and exposed from the protection layer 117, is covered with a laminated film including the insulating film 118A and reflection film 118B. The laminated film is provided continuously for the plurality of light-emitting elements 11. The laminated film has an opening 118H on the surface 11S2 side of each light-emitting element 11, and the plug 15 is provided in the opening 118H. The insulating film 118A includes, for example, an insulating material such as silicon oxide (SiO) or silicon nitride (SiN). Examples of the reflection film 118B include a metal having a high reflectance in a visible light region. Examples of the specific material include silver (Ag), aluminum (Al), copper (Cu), gold (Au), platinum (Pt), rhodium (Rh), and any alloy of these.

The embedding layer 119 is embedded with the plurality of light-emitting elements 11 and provides flat front surface and back surface of the light-emitting section 10. The embedding layer 119 includes, for example, an insulating material such as silicon oxide (SiO) or silicon nitride (SIN).

The embedding layer 119 has, as described above, the gap G in the separation section 11H separating the compound semiconductor layer 110 into the plurality of light-emitting elements 11. For example, in annealing during the manufacturing process of the light-emitting device 1, the gap G absorbs a stress in the XY plane direction due to a difference in a coefficient of thermal expansion between the compound semiconductor layer 110 including, for example, GaN and the embedding layer 119 around the compound semiconductor layer 110 or between the compound semiconductor layer 110 and a support substrate 31 including, for example, silicon (SI) in the drive substrate 30. The gap G is provided between two or more of the light-emitting elements 11 adjacent to each other in the XY plane direction. Specifically, the gap G is provided between opposing sides of two or more of the light-emitting elements each having a substantially equilateral hexagonal shape, for example as illustrated in FIG. 3. An intersection between neighboring ones of the light-emitting elements 11 separated by the separation section 11H may be filled with the embedding layer 119 or may be provided with the gap G.

As illustrated in FIG. 3, the gap G is preferable to have a width (W) in the in-XY-plane direction (opposed direction of opposing sides of adjacent ones of the light-emitting elements 11) equal to or wider than a coefficient of thermal expansion of the compound semiconductor layer 110×a length (L) of each piece of the compound semiconductor layer 110 separated by the separation section 11H×400° C., for example. Here, 400° C. is a maximum temperature assumed in annealing during a BEOL process including Cu—Cu jointing of a plurality of the pads 19 and 34 on the light-emitting section 10 side and the drive substrate 30 side of the light-emitting device 1 to be described below. This makes it possible to suppress occurrence of cracks around the light-emitting elements 11 due to a difference in a coefficient of thermal expansion between the compound semiconductor layer 110 and the embedding layer 119 around the compound semiconductor layer 110 or between the compound semiconductor layer 110 and the support substrate 31.

The plug 15 applies a voltage to the first electric conductivity type layer 111 of each of the plurality of light-emitting elements 11. The plug 15 is formed using, for example, copper (Cu), aluminum (Al), tungsten (W), silver (Ag), any alloy of these, or the like.

On the drive substrate 30 side of the embedding layer 119, the insulating layer 17 is provided. In the insulating layer 17, a plurality of the pads 16A provided for the respective light-emitting elements 11A in the display region 100A, a plurality of the pad electrodes 16B provided in the frame region 100B, and vias are provided. The insulating layer 17 includes, for example, silicon oxide (SiO), silicon nitride (SiN), or the like. The pads 16A, pad electrodes 16B, and vias are each formed using, for example, copper (Cu), aluminum (Al), tungsten (W), silver (Ag), any alloy of these, or the like.

On the drive substrate 30 side of the insulating layer 17, the insulating layer 18 forming a joint surface with respect to the drive substrate 30 and the pads 19 formed embedded in the insulating layer 18 are further provided. The insulating layer 18 includes, for example, silicon oxide (SiO), silicon nitride (SiN), or the like. The pads 19 are formed using, for example, copper (Cu).

The wavelength conversion section 20 is disposed on a light extraction surface S1 side of the light-emitting section 10. The wavelength conversion section 20 includes a flattening layer 21, a partition wall layer 22, and a wavelength conversion layer 23, the partition wall layer 22 having an opening 22H for each of the light-emitting elements 11, for example, and the wavelength conversion layer 23 provided in the opening 22H. Between the partition wall layer 22 and the wavelength conversion layer 23, a reflection film 24 is further provided. On the light extraction surface S1 side of the wavelength conversion layer 23, a protection layer 25 is further provided. In the protection layer 25, a wavelength selection layer 26 is provided. On the protection layer 25, an on-chip lens layer 27 is further provided.

The flattening layer 21 is provided to flatten a surface on the light extraction surface S1 side of the light-emitting section 10. The flattening layer 21 includes, for example, silicon oxide (SiO), silicon nitride (SiN), or the like.

The partition wall layer 22 is provided to suppress occurrence of color mixture due to light leakage between adjacent RGB sub-pixels (red color pixel Pr, green color pixel Pg, and blue color pixel Pb), in application of the light-emitting device 1 to the image display apparatus 100. The partition wall layer 22 has, for example, a honeycomb structure. Specifically, the partition wall layer 22 has the opening 22H of, for example, substantially equilateral hexagonal shape for each of the plurality of light-emitting elements 11 arranged in an array, as illustrated in FIG. 3. The opening 22H includes, in cross-sectional view, an inclined surface of less than 90° with respect to a surface 20S2 opposite to a surface 20S1 of the wavelength conversion section 20, for example. In other words, the partition wall layer 22 has a forward tapered shape between adjacent color pixels Pr, Pg, and Pb, in cross-sectional view. The partition wall layer 22 is preferable to be formed using a material high in thermal conductivity and electric conductivity. The partition wall layer 22 is formed using, for example, a metal material such as copper (Cu), aluminum (Al), gold (Au), nickel (Ni), or platinum (Pt).

The wavelength conversion layer 23 is provided to convert light emitted from the plurality of light-emitting elements 11 into a desired wavelength (for example, red (R)/green (G)/blue (B)) to output the light. The wavelength conversion layer 23 is provided in the opening 22H provided above each light-emitting element 11. Specifically, in the red color pixel Pr, a red color wavelength conversion layer 23R that converts light emitted from the light-emitting element 11 into light (red light) in a red bandwidth is provided. In the green color pixel Pg, a green color wavelength conversion layer 23G that converts light emitted from the light-emitting element 11 into light (green light) in a green bandwidth is provided. In the blue color pixel Pb, a blue color wavelength conversion layer 23B that converts light emitted from the light-emitting element 11 into light (blue light) in a blue bandwidth is provided.

The wavelength conversion layers 23R, 23G, and 23B are possible to be formed using quantum dots corresponding to the respective colors. Specifically, in a case of obtaining red light, the quantum dots are possible to be selected from, for example, InP, GaInP, InAsP, CdSe, CdZnSe, CdTeSe, CdTe, or the like. In a case of obtaining green light, the quantum dots are possible to be selected from, for example, InP, GaInP, ZnSeTe, ZnTe, CdSe, CdZnSe, CdS, CdSeS, or the like. In a case of obtaining blue light, the quantum dots are possible to be selected from ZnSe, ZnTe, ZnSeTe, CdSe, CdZnSe, CdS, CdZnS, CdSeS, or the like. Note that, in a case where blue light is emitted from the light-emitting element 11 as described above, the blue color wavelength conversion layer 23B may include a resin layer having optical transparency.

The reflection film 24 is provided to efficiently extract, from a light extraction surface (surface 22S1) of the wavelength conversion layer 23, light of the respective colors that has been emitted from the light-emitting element 11 and converted in the respective wavelength conversion layers 23R, 23G, and 23B. The reflection film 24 is provided on a side surface of the opening 22H. The reflection film 24 is formed using a metal material having light reflectivity. Examples of the metal material for the reflection film 24 to be formed include a metal having a high reflectance in a visible light region. Examples of the specific material include silver (Ag), aluminum (Al), copper (Cu), gold (Au), platinum (Pt), rhodium (Rh), and any alloy of these.

Note that the reflection film 24 need not necessarily be provided in a case where the partition wall layer 22 is formed using the above-described metal material having light reflectivity.

The protection layer 25 is provided to protect a surface of the light-emitting device 1 and includes, for example, silicon oxide (SiO), silicon nitride (SiN), or the like.

In the protection layer 25, the wavelength selection layer 26 is provided over the red color pixel Pr and green color pixel Pg. The wavelength selection layer 26 is, for example, one that selectively reflects light (blue light) in a blue bandwidth, and allows color purity of red light and green light respectively extracted from the red color pixel Pr and green color pixel Pg to be enhanced.

The on-chip lens layer 27 is provided covering all the surface of the display region 100A and frame region 100B. The on-chip lens layer 27 includes a material having optical transparency. For example, the on-chip lens layer 27 includes a single layer film formed of any one out of silicon oxide (SiO), silicon nitride (SiN), silicon oxynitride (SiCN), and the like, or a laminated film formed of two or more types out of them.

In the frame region 100B, an opening H2 is provided that penetrates the on-chip lens layer 27, the protection layer 25, the partition wall layer 22, the flattening layer 21, the insulating layer 13, the embedding layer 119, and the protection layer 117 and reaches a pad electrode 18B. The pad electrode 18B exposed in a bottom of the opening H2 is used as a coupling electrode to the outside.

The drive substrate 30 is provided with a drive circuit or the like that controls driving of the plurality of light-emitting elements 11 arranged in the display region 100A. The drive substrate 30 includes, for example, the support substrate 31, an interlayer insulating layer 32, an insulating layer 33, and pads 34, the support substrate 31 including silicon (Si), the interlayer insulating layer 32 provided on the support substrate 31 and including a plurality of wiring layers (for example, wiring layers M1, M2, M3, M4, and M5) and vias that electrically couple the wiring layers, the insulating layer 33 forming a joint surface with respect to the light-emitting section 10, the pads 34 formed embedded in the insulating layer 33.

The interlayer insulating layer 32 includes, for example, silicon oxide (SiO), silicon nitride (SiN), or the like.

The wiring layers M1, M2, M3, M4, and M5 and the vias that electrically couple the wiring layers are formed using, for example, copper (Cu), aluminum (Al), tungsten (W), silver (Ag), any alloy of these, or the like. The insulating layer 33 includes, for example, silicon oxide (SiO), silicon nitride (SiN), or the like. Pads 35 are formed using, for example, copper (Cu).

### (1-2. Manufacturing Method of Light-emitting Device)

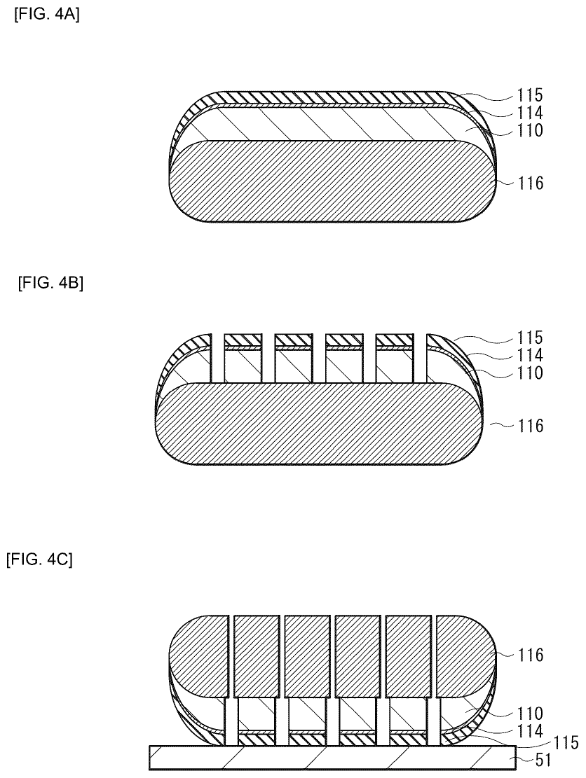

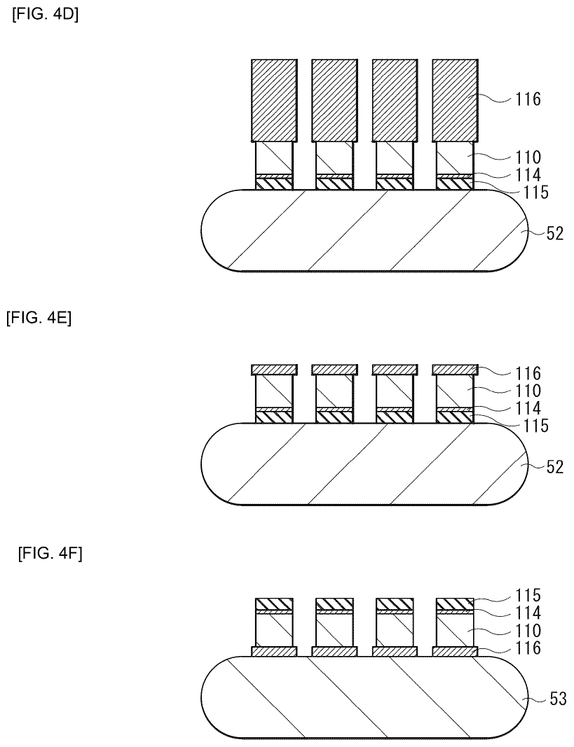

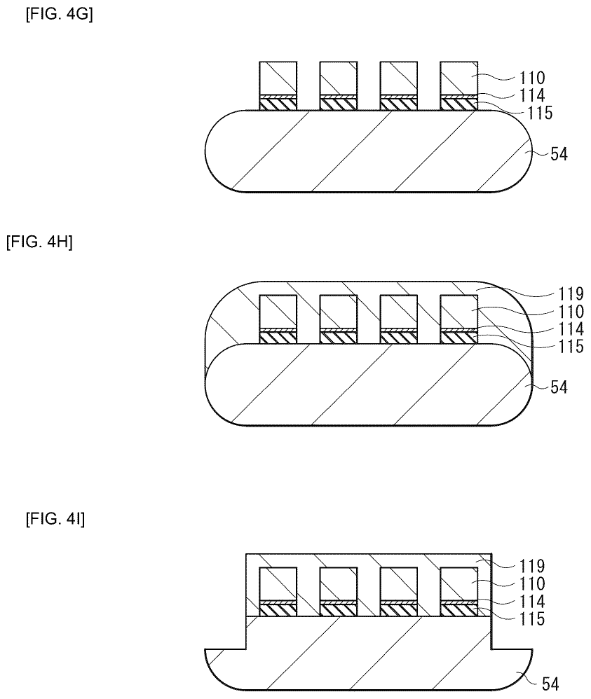

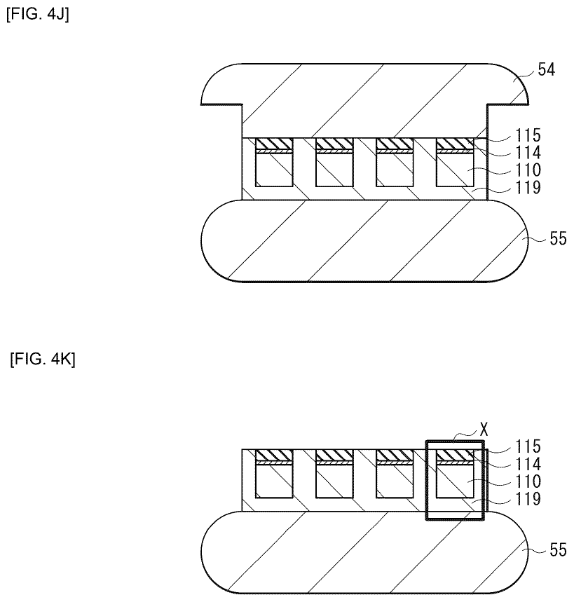

The light-emitting device 1 according to the present embodiment is, for example, possible to be manufactured as below. FIGS. 4A to 4K and 5A to 5W each illustrate an example of a manufacturing process of the light-emitting device 1.

First, as illustrated in FIG. 4A, for example with a sapphire substrate 116 as a growth substrate, the compound semiconductor layer 110 is formed by epitaxial crystalline growth using a method such as a metal organic chemical vapor deposition (MOCVD) method or molecular beam epitaxy (MBE) method. Subsequently, on the compound semiconductor layer 110, the electrode layer 114 and insulating layer 115 are formed by a chemical vapor deposition (CVD) method, for example. Next, a surface of the insulating layer 115 is flattened by chemical mechanical polishing (CMP), for example.

Subsequently, as illustrated in FIG. 4B, the insulating layer 115, electrode layer 114, and compound semiconductor layer 110 are, for example by using photolithography, etched and patterned. Next, as illustrated in FIG. 4C, the sapphire substrate 116 is transferred to allow the insulating layer 115 to face a support substrate 51, and then the sapphire substrate 116 is cut off to be individual pieces. Subsequently, as illustrated in FIG. 4D, the individual pieces of the sapphire substrate 116 are bonded to allow the insulating layer 115 to face a transfer substrate 52.

Next, as illustrated in FIG. 4E, for example by grinding and polishing, the sapphire substrate 116 is thinned to have a thickness of, for example, 500 nm. Subsequently, as illustrated in FIG. 4F, on the sapphire substrate 116 side, a reverse substrate 53 is bonded and reversed, and then the transfer substrate 52 is peeled off. Next, after the surface of the insulating layer 115 is again flattened, for example by CMP, as illustrated in FIG. 4G, the insulating layer 115 is jointed to a support substrate 54 and the sapphire substrate 116 is removed, for example by grinding and polishing.

Subsequently, as illustrated in FIG. 4H, for example by a CVD method, the embedding layer 119 is formed on the support substrate 54 and is flattened. Next, as illustrated in FIG. 4I, an end portion of the support substrate 54 is trimmed. Next, as illustrated in FIG. 4J, for example by plasma jointing, the embedding layer 119 is joined to a support substrate 55, and then the support substrate 54 is peeled off. Hereinafter, description is made with a portion within frame X illustrated in FIG. 4K enlarged.

First, as illustrated in FIG. 5A, the insulating layer 115 and the electrode layer 114 are, for example by using photolithography, etched and patterned. Subsequently, as illustrated in FIG. 5B, a portion of the compound semiconductor layer is, for example by using photolithography, etched and a mesa structure including the first electric conductivity type layer 111, the light-emitting region 112, and the portion of the second electric conductivity type layer 113 is formed.

Next, for example by an atomic layer deposition (ALD) method, an AlO film is formed over a top surface of the insulating layer 115, side surfaces of the insulating layer 115 and electrode layer 114 and of the first electric conductivity type layer 111, light-emitting region 112, and second electric conductivity type layer 113 included in the mesa structure, and a bottom surface, and then an SiN film is further formed by, for example, a CVD method. Thereafter, the SiN film is, for example by using photolithography, etched and thereby, as illustrated in FIG. 5C, the protection layer 117 as a side wall is formed on a top surface and side surface of the mesa structure.

Subsequently, as illustrated in FIG. 5D, for example by using photolithography, for example, the separation section 11H penetrating the second electric conductivity type layer 113 exposed from the protection layer 117 and penetrating the sapphire substrate 116 is formed to thereby form the plurality of light-emitting elements 11. Next, for example by an ALD method, an AlO film is formed covering a top surface of the protection layer 117 and a side surface of each of the light-emitting elements 11 exposed. Subsequently, as illustrated in FIG. 5E, for example by a CVD method, the insulating film 118A and the reflection film 118B are formed in order, and then the opening 118H is formed in the top surface of the mesa structure.

Next, as illustrated in FIG. 5F, for example by a CVD method, the embedding layer 119 is further formed. At this time, the gap G is formed between adjacent ones of the light-emitting elements 11. Thereafter, the embedding layer 119 is flattened and then, as illustrated in FIG. 5G, the insulating layer 17 embedded with the plug 15 for each of the light-emitting elements 11, the plurality of pads 16A, and the pad electrodes 16B is formed. Subsequently, as illustrated in FIG. 5H, the insulating layer 17 is thickened and the insulating layer 18 is formed on the insulating layer 17, and then, as illustrated in FIG. 5I, an end portion is trimmed.

Next, as illustrated in FIG. 5J, an opening 18H is formed on each of the pads 16A and pad electrodes 16B, and then, as illustrated in FIG. 5K, the plurality of pads 19 is formed by embedding, for example, Cu in the opening 18H. Thereafter, surfaces of the insulating layer 18 and the plurality of pads 19 are polished by, for example, CMP to flatten a joint surface with respect to the drive substrate 30.

Subsequently, as illustrated in FIG. 5L, the plurality of pads 34 of the drive substrate 30 having formed separately and the plurality of pads 19 are bonded by Cu-Cu jointing at 400° C., for example. Thereafter, as illustrated in FIG. 5M, the support substrate 55 is peeled off. Next, as illustrated in FIG. 5N, for example by using photolithography, surfaces (specifically, second electric conductivity type layer 113) of the plurality of light-emitting elements 11 are exposed. Subsequently, as illustrated in FIG. 50, for example by a CVD method, an ITO film is formed, and then, for example by using photolithography, the ITO film is patterned to form the electrode layer 12.

Next, as illustrated in FIG. 5P, for example by a CVD method, the insulating layer 13 is formed and, for example by using photolithography, the opening 13H is formed between adjacent ones of the light-emitting elements 11, and then, as illustrated in FIG. 5Q, for example by using photolithography, the opening H1 reaching any of the pad electrodes 16B is formed. Subsequently, for example by a CVD method, a laminated film, for example of Ti/W, is formed, and then, for example by using photolithography, the laminated film is patterned to form the extraction electrode 14 as illustrated in FIG. 5R.

Next, as illustrated in FIG. 5S, for example by a CVD method, the flattening layer 21 and the partition wall layer 22 are formed in order. Subsequently, as illustrated in FIG. 5T, for example by using photolithography, the opening 22H is formed in the partition wall layer 22 above each light-emitting element 11. Next, as illustrated in FIG. 5U, for example by a CVD method, an Al film is formed on a top surface of the partition wall layer 22 and on a side surface and bottom surface of the opening 22H, and then, by etch back, the Al film formed on the top surface of the partition wall layer 22 and the bottom surface of the opening 22H is removed to form the reflection film 24 on the side surface of the opening 22H.

Subsequently, as illustrated in FIG. 5V, in the opening 22H, for example by using an application method such as an ink jet method, the wavelength conversion layer 23 of the respective colors (23R, 23G, and 23B) is formed. Thereafter, as illustrated in FIG. 5W, on the partition wall layer 22 and wavelength conversion layer 23, the protection layer 25 including the wavelength selection layer 26 is formed, and then the on-chip lens layer 27 is bonded. As described above, the light-emitting device 1 illustrated in FIG. 1 is completed.

### (1-3. Operations and Effects)

In the light-emitting device 1 according to the present embodiment, the separation section 11H separating the compound semiconductor layer 110 electrically coupled to the drive substrate 30 is provided to form the plurality of light-emitting elements 11, and the separation section 11H is embedded with the embedding layer 119. The embedding layer 119 has the gap G between adjacent ones of the light-emitting elements 11. This allows an expansion of the compound semiconductor layer 110 due to, for example, annealing during the manufacturing process to be absorbed by the gap G, preventing occurrence of cracks around the compound semiconductor layer 110. This will be described below.

In recent years, a high-definition image display apparatus using a light-emitting device including, as a light source, a micro LED using gallium nitride (GaN) has become popular. For such a light-emitting device, in the manufacturing process, a process is included where individual pieces of GaN chip are arranged on a substrate and jointed and a sapphire substrate as a growth substrate is processed by laser lift-off. In such a process, in order to ensure a jointing strength between the substrate and the GaN chip, a method is used and considered where a covalent bond is caused by dehydration condensation reaction at the interface between the GaN chip and the substrate by warming while applying a load, for example.

Meanwhile, since the GaN chip has internal stress, cracks may occur in a surrounding structure, due to a coefficient of thermal expansion between the GaN chip and an insulating film around the GaN chip or between the GaN chip and an Si substrate in annealing or the like during a BEOL process.

In contrast, in the present embodiment, the embedding layer 119 is embedded having the gap G between the plurality of light-emitting elements 11 obtained by the compound semiconductor layer 110 being separated into a plurality of pieces by the separation section 11H. This makes it possible to suppress occurrence of cracks around the light-emitting elements 11 due to a difference in a coefficient of thermal expansion between the compound semiconductor layer 110 and the embedding layer 119 around the compound semiconductor layer 110 or between the compound semiconductor layer 110 and the support substrate 31.

As described above, it is possible to enhance reliability of the light-emitting device 1 according to the present embodiment and the image display apparatus 100 provided with the light-emitting device 1.

### 2. Modification

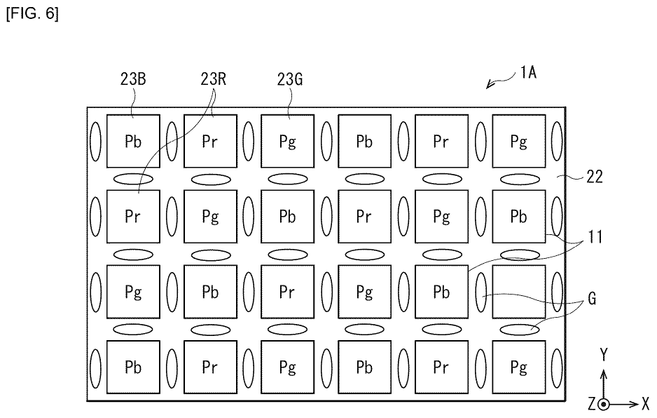

Although, in the embodiment described above, an example is illustrated where the plurality of light-emitting elements 11 each has the opening 22H of a substantially equilateral hexagonal shape, the shape of the plurality of light-emitting elements 11 in plan view is not limited to this. For example, as illustrated in FIG. 6, the plurality of light-emitting elements 11 may each have a polygonal shape including a square, a rectangle, and a trapezoid or a circular shape including an ellipse. In any case, the gap G is provided between two or more light-emitting elements 11 adjacent to each other in the XY plane direction. An intersection between neighboring ones of the light-emitting elements 11 separated by the separation section 11H may be filled with the embedding layer 119 or may be provided with the gap G.

Note that, as illustrated in FIG. 6, in a case where the plurality of light-emitting elements 11 each has a substantially square shape, the wavelength conversion layers 23 (red color wavelength conversion layer 23A, green color wavelength conversion layer 23G, and blue color wavelength conversion layer 23B) provided above the light-emitting elements 11 are arranged in Bayer arrangement, for example.

### 3. Application Examples

### (Application Example 1)

FIG. 7 is a perspective view illustrating an example of a schematic configuration of an image display apparatus (image display apparatus 100). The image display apparatus 100 is a so-called LED display. In the image display apparatus 100, the light-emitting device (for example, light-emitting device 1) of the present disclosure is used as a display pixel. The image display apparatus 100 includes a display panel 120 and a control circuit 140 that drives the display panel 120, for example as illustrated in FIG. 7.

The display panel 120 includes a mounting substrate 120A and a counter substrate 120B overlapping with each other. A surface of the counter substrate 120B is a picture display surface including a display region (display region 100A) at the center part and the frame region 100B around the display region, the frame region 100B being a non-display region.

FIG. 8 illustrates an example of a wiring layout of a region, corresponding to the display region 100A, within a surface on the counter substrate 120B side of the mounting substrate 120A. The region, corresponding to the display region 100A, within the surface of the mounting substrate 120A is provided with, for example as illustrated in FIG. 8, a plurality of data wirings 121 formed extending in a predetermined direction, the plurality of data wirings 121 arranged in parallel at predetermined pitches. The region, corresponding to the display region 100A, within the surface of the mounting substrate 120A is further provided with, for example, a plurality of scanning wirings 122 formed extending in a direction intersecting with (for example, orthogonal to) the data wirings 121, the plurality of scanning wirings 122 arranged in parallel at predetermined pitches. The data wirings 121 and the scanning wirings 122 include, for example, an electric conductive material such as Cu.

The scanning wirings 122 are formed, for example, on the outermost layer. For example, the scanning wirings 122 are formed on an insulation layer (not illustrated) formed on a base surface. Note that the base of the mounting substrate 120A includes, for example, a silicon substrate or a resin substrate, and that the insulation layer on the base includes, for example, SiN, SiO, aluminum oxide (AlO), or resin material. Meanwhile, the data wirings 121 are formed in a layer (for example, layer lower than the outermost layer) different from the outermost layer including the scanning wirings 122. For example, the data wirings 121 are formed in the insulation layer on the base.

A vicinity of a point at which any one of the data wirings 121 and any one of the scanning wirings 122 intersect corresponds to a display pixel 123. A plurality of the display pixels 123 is arranged in matrix in the display region 100A. For example, the color pixels Pr, Pg, and Pb of the light-emitting device 1 are implemented on the display pixels 123.

The light-emitting device 1 is, for example, provided with a pair of terminal electrodes for each of the color pixels Pr, Pg, and Pb, or provided with one terminal electrode disposed common to the color pixels Pr, Pg, and Pb and other ones disposed for the respective color pixels Pr, Pg, and Pb. The one terminal electrode is electrically coupled to a corresponding one of the data wirings 121 and the other terminal electrode(s) is electrically coupled to a corresponding one of the scanning wirings 122. For example, the one terminal electrode is electrically coupled to a pad electrode 121B at a tip of a branch 121A provided for the data wiring 121. Further, for example, the other terminal electrode is electrically coupled to a pad electrode 122B at a tip of a branch 122A provided for the scanning wiring 122.

The pad electrodes 121B and 122B are formed, for example, on the outermost layer, and provided for a part where each light-emitting device 1 is implemented on, for example as illustrated in FIG. 8. Here, each of the pad electrodes 121B and 122B includes, for example, an electric conductive material such as Au (gold).

The mounting substrate 120A is further provided with, for example, a plurality of posts (not illustrated) restricting a gap between the mounting substrate 120A and the counter substrate 120B. The posts may be provided in a region opposed to the display region 100A or may be provided in a region opposed to the frame region 100B.

The counter substrate 120B includes, for example, a glass substrate or a resin substrate. A surface on the light-emitting device 1 side of the counter substrate 120B may be flat, but preferably be a rough surface. The rough surface may be provided over a whole of a region opposed to the display region 100A or may be provided only in a region opposed to the display pixels 123. The rough surface that light emitted from the color pixels Pr, Pg, and Pb enters has fine irregularities. The irregularities of the rough surface are possible to be produced by, for example, sand blasting or dry etching.

The control circuit 140 drives each display pixel 123 (each light-emitting device 1) on the basis of a picture signal. The control circuit 140 includes, for example, a data driver that drives the data wirings 121 each coupled to the display pixel 123 and a scanning driver that drives the scanning wirings 122 each coupled to the display pixel 123. The control circuit 140 may be, for example as illustrated in FIG. 7, provided separately from the display panel 120 and coupled to the mounting substrate 120A via a wiring, or may be mounted on the mounting substrate 120A.

### (Application Example 2)

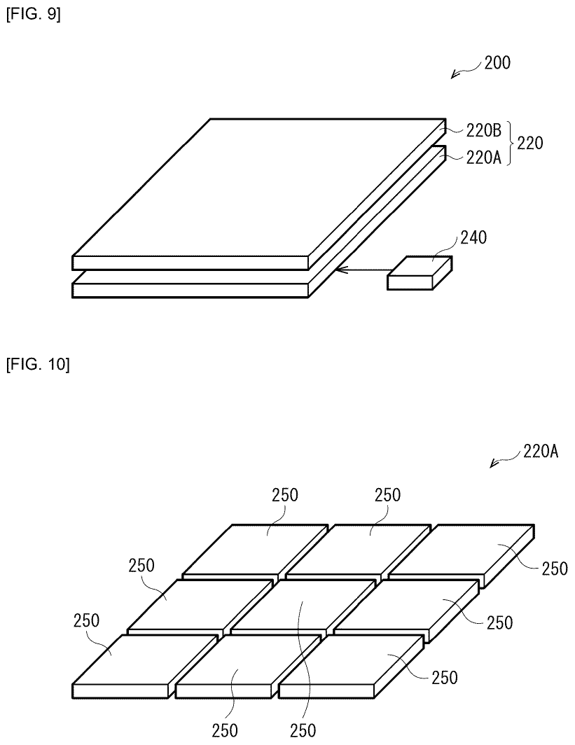

FIG. 9 is a perspective view illustrating another configuration example of an image display apparatus (image display apparatus 200) using the light-emitting device (for example, light-emitting device 1) of the present disclosure. The image display apparatus 200 is a so-called tiling display, using a plurality of the light-emitting devices each with an LED as a light source. The image display apparatus 200 includes a display panel 220 and a control circuit 240 that drives the display panel 220, for example as illustrated in FIG. 9.

The display panel 220 includes a mounting substrate 220A and a counter substrate 220B overlapping with each other. A surface of the counter substrate 220B is a picture display surface including a display section at the center part and a frame section around the display section (both not illustrated), the frame section being a non-display region. The counter substrate 220B is disposed at a position opposed to the mounting substrate 220A, with a predetermined gap interposed, for example. Note that the counter substrate 220B may be in contact with a top surface of the mounting substrate 220A.

FIG. 10 schematically illustrates an example of a configuration of the mounting substrate 220A. The mounting substrate 220A includes, for example as illustrated in FIG. 10, a plurality of unit substrates 250 laid in a tile-like shape. Note that, in FIG. 10, although an example is described where the mounting substrate 220A includes nine unit substrates 250, the number of the unit substrates 250 may be ten or more, or may be eight or less.

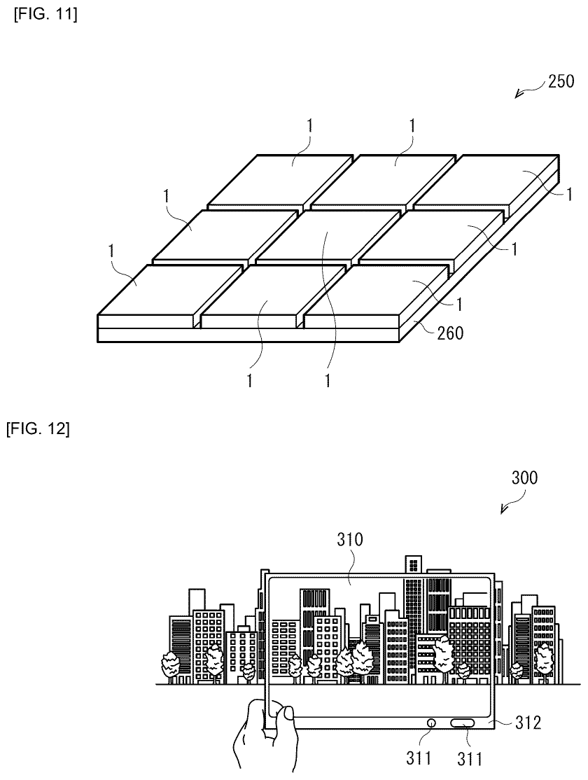

FIG. 11 illustrates an example of a configuration of each unit substrate 250. The unit substrate 250 includes, for example, a plurality of the light-emitting devices 1 laid in a tile-like shape and a support substrate 260 supporting the respective light-emitting devices 1. Each unit substrate 250 further includes a control substrate (not illustrated). The support substrate 260 includes, for example, a metal frame (metal plate) or a wiring substrate. In a case where the support substrate 260 includes the wiring substrate, the support substrate 260 is possible to serve as the control substrate. In this case, the support substrate 260, the control substrate, or both are electrically coupled to the respective light-emitting devices 1.

### (Application Example 3)

FIG. 12 illustrates an external appearance of a transparent display 300. The transparent display 300 includes, for example, a display section 310, operation sections 311, and a housing 312. For the display section 310, the light-emitting device (for example, light-emitting device 1) of the present disclosure is used. The transparent display 300 allows an image or textual information to be displayed with a background of the display section 310 seen through.

For a mounting substrate of the transparent display 300, a substrate having optical transparency is used. Each electrode provided in the light-emitting device 1 is, similarly to the mounting substrate, formed using an electric conductive material having optical transparency. Alternatively, each electrode has a structure difficult to be visually recognized, by complementing a wiring width or reducing the wiring in thickness. Further, for example, the transparent display 300 allows black display with a liquid crystal layer including a drive circuit overlapped, and allows switching between transparency and black display with the illumination direction of the liquid crystal controlled.

While a technique of the present disclosure has been described above providing the embodiment, modification, and application examples, the technique of the present disclosure is not limited to the embodiments or the like described above and is possible to be modified in various ways. For example, in the embodiments and the like described above, although an example is described where light emitted from the light-emitting elements 11 is blue light or ultraviolet light, the present disclosure is not limited to this. For example, in the light-emitting device 1, it is possible to use a light-emitting element that emits two or more types of light such as blue light and green light or ultraviolet light and green light.

Moreover, in the embodiment and the like described above, although an example is described where the separation section 11H separating the compound semiconductor layer 110 into the plurality of light-emitting elements 11 penetrates the compound semiconductor layer 110 from the surface 11S2 side, the present disclosure is not limited to this. The separation section 11H may be provided from both the surface 11S1 side and surface 11S2 side of the compound semiconductor layer 110. In such a case, one or both of the separation sections provided from both the surface 11S1 side and surface 11S2 side of the compound semiconductor layer 110 have the gap G. With this, it is possible to achieve effects similar to that of the embodiments described above.

Furthermore, in the embodiments and the like described above, although description has been made specifically for the respective members included in the light-emitting device 1 or the like, not all the members need to be provided. Another member may further be provided.

Note that the effects described herein are merely examples, which are not limited to the description thereof. Another effect may be exhibited.

The technique of the present disclosure is possible to have a configuration as below. According to the technique of the present disclosure with the following configuration, the separation section separating the compound semiconductor layer into a plurality of pieces is embedded with the embedding layer and adjacent pieces of the compound semiconductor layer have the gap therebetween. This allows an expansion of the compound semiconductor layer due to, for example, annealing during the manufacturing process to be absorbed by the gap, preventing occurrence of cracks. Thus, this makes it possible to enhance reliability.

(1)

A light-emitting device including:
a drive substrate;
a compound semiconductor layer electrically coupled to the drive substrate, the compound semiconductor layer including
   a first surface opposed to the drive substrate,
   a second surface that is opposite to the first surface and that serves as a light output surface, and
   a light-emitting region between the first surface and the second surface;
a separation section separating, from the first surface toward the second surface, the compound semiconductor layer into a plurality of pieces; and
an embedding layer that is provided between the drive substrate and the compound semiconductor layer, that is embedded in the separation section, and that has a gap between adjacent pieces of the compound semiconductor layer.
   (2)

The light-emitting device according to (1), in which the plurality of pieces of the compound semiconductor layer separated by the separation section each has a polygonal shape including a square, a rectangle, and a trapezoid or a circular shape including an ellipse in plan view.

(3)

The light-emitting device according to (1) or (2), in which a reflection film is provided, via an insulating film, on a side surface of each of the plurality of pieces of the compound semiconductor layer separated by the separation section.

(4)

The light-emitting device according to any one of (1) to (3), in which a width of the gap in an in-plane direction of the compound semiconductor layer is equal to or more than a coefficient of thermal expansion of the compound semiconductor layer x a length of each of the plurality of pieces of the compound semiconductor layer separated by the separation section×400° C.

(5)

The light-emitting device according to any one of (1) to (4), in which adjacent pieces of the compound semiconductor layer have the gap therebetween, and the plurality of pieces of the compound semiconductor layer separated by the separation section have an intersection embedded with the embedding layer.

(6)

The light-emitting device according to any one of (1) to (4), further including a pixel array section including a plurality of pixels arranged in an array, in which
each of the plurality of pixels includes a light-emitting element obtained by separation of the compound semiconductor layer by the separation section for the respective pixels, and
a wavelength conversion layer that converts a wavelength of light emitted from the light-emitting element is further provided on a side of the light output surface of the light-emitting element.
   (7)

The light-emitting device according to (6), in which
the plurality of pixels includes a first pixel, a second pixel, and a third pixel,
the first pixel includes, as the wavelength conversion layer, a first wavelength conversion layer that converts the light emitted from the light-emitting element into red light,
the second pixel includes, as the wavelength conversion layer, a second wavelength conversion layer that converts the light emitted from the light-emitting element into green light, and
the third pixel includes, as the wavelength conversion layer, a third wavelength conversion layer that transmits the light emitted from the light-emitting element or converts the light emitted from the light-emitting element into blue light.
   (8)

An image display apparatus including
a light-emitting device, in which
the light-emitting device includes
   a drive substrate,
   a compound semiconductor layer electrically coupled to the drive substrate, the compound semiconductor layer including
      a first surface opposed to the drive substrate,
      a second surface that is opposite to the first surface and that serves as a light output surface, and
      a light-emitting region between the first surface and the second surface,
   a separation section separating, from the first surface toward the second surface, the compound semiconductor layer into a plurality of pieces, and
   an embedding layer that is provided between the drive substrate and the compound semiconductor layer, that is embedded in the separation section, and that has a gap between adjacent pieces of the compound semiconductor layer.

The present application claims the benefit of Japanese Priority Patent Application JP2023-054169 filed with the Japan Patent Office on Mar. 29, 2023, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A light-emitting device comprising:
a drive substrate;
a compound semiconductor layer electrically coupled to the drive substrate, the compound semiconductor layer including
a first surface opposed to the drive substrate,
a second surface that is opposite to the first surface and that serves as a light output surface, and
a light-emitting region between the first surface and the second surface;
a separation section separating, from the first surface toward the second surface, the compound semiconductor layer into a plurality of pieces; and
an embedding layer that is provided between the drive substrate and the compound semiconductor layer, that is embedded in the separation section, and that has a gap between adjacent pieces of the compound semiconductor layer.

2. The light-emitting device according to claim 1, wherein the plurality of pieces of the compound semiconductor layer separated by the separation section each has a polygonal shape including a square, a rectangle, and a trapezoid or a circular shape including an ellipse in plan view.

3. The light-emitting device according to claim 1, wherein a reflection film is provided, via an insulating film, on a side surface of each of the plurality of pieces of the compound semiconductor layer separated by the separation section.

4. The light-emitting device according to claim 1, wherein a width of the gap in an in-plane direction of the compound semiconductor layer is equal to or more than a coefficient of thermal expansion of the compound semiconductor layer×a length of each of the plurality of pieces of the compound semiconductor layer separated by the separation section×400° C.

5. The light-emitting device according to claim 1, wherein adjacent pieces of the compound semiconductor layer have the gap therebetween, and the plurality of pieces of the compound semiconductor layer separated by the separation section have an intersection embedded with the embedding layer.

6. The light-emitting device according to claim 1, further comprising a pixel array section including a plurality of pixels arranged in an array, wherein
each of the plurality of pixels includes a light-emitting element obtained by separation of the compound semiconductor layer by the separation section for the respective pixels, and
a wavelength conversion layer that converts a wavelength of light emitted from the light-emitting element is further provided on a side of the light output surface of the light-emitting element.

7. The light-emitting device according to claim 6, wherein
the plurality of pixels includes a first pixel, a second pixel, and a third pixel,
the first pixel includes, as the wavelength conversion layer, a first wavelength conversion layer that converts the light emitted from the light-emitting element into red light,
the second pixel includes, as the wavelength conversion layer, a second wavelength conversion layer that converts the light emitted from the light-emitting element into green light, and
the third pixel includes, as the wavelength conversion layer, a third wavelength conversion layer that transmits the light emitted from the light-emitting element or converts the light emitted from the light-emitting element into blue light.

8. An image display apparatus comprising
a light-emitting device, wherein
the light-emitting device includes
a drive substrate,
a compound semiconductor layer electrically coupled to the drive substrate, the compound semiconductor layer including
a first surface opposed to the drive substrate,
a second surface that is opposite to the first surface and that serves as a light output surface, and
a light-emitting region between the first surface and the second surface,
a separation section separating, from the first surface toward the second surface, the compound semiconductor layer into a plurality of pieces, and
an embedding layer that is provided between the drive substrate and the compound semiconductor layer, that is embedded in the separation section, and that has a gap between adjacent pieces of the compound semiconductor layer.
